(19) United States
(12) Patent Application Publication
(10) Pub. No.: US 2026/0255492 A1
(43) Pub. Date: Aug. 27, 2026

(54) LIQUID CRYSTAL POLYMER DIELECTRIC POWDER OR 3D PRINTED MATERIAL

(71) Applicant: LCP Medical Technologies, LLC, Rogers, MN (US)

(72) Inventor: James RATHBURN, Rogers, MN (US)

(21) Appl. No.: 19/160,187

(22) PCT Filed: Feb. 27, 2024
(86) PCT No.: PCT/US2024/017576

§ 371 Date: Aug. 27, 2025

Related U.S. Application Data
(60) Provisional application No. 63/487,213, filed on Feb. 27, 2023.

(51) Int. Cl. H05K 3/00; C08K 3/08; H05K 1/03; H05K 3/02; H05K 3/10; H05K 3/18

(52) U.S. Cl. CPC H05K 3/0014; C08K 3/08; H05K 1/0373; H05K 3/027; H05K 3/107; H05K 3/184; C08K 2003/085; C08K 2003/0862; H05K 2201/0141; H05K 2203/1105

(57) ABSTRACT

Embodiments for a method of forming a circuit bearing structure are provided. The method includes depositing a layer of thermoplastic particles on a surface, pressing and heating the layer of thermoplastic particles to create a contiguous thermoplastic film, and forming one or more circuit structures in the contiguous thermoplastic film.

### RELATED APPLICATIONS

This application claims the benefit of U.S. Provisional Application No. 63/487,213 , entitled “LIQUID CRYSTAL POLYMER DIELECTRIC POWDER OR 3D PRINTED MATERIAL”, which is hereby incorporated herein by reference.

### BACKGROUND

Traditional printed circuits are often constructed in either rigid or flexible formats. In a rigid format, the printed circuit board (PCB) is a laminate of materials including circuits that when completed is stiff and cannot bend significantly without damage. Flexible circuits have become popular more recently in many applications where the ability to bend the circuit to connect one member of a system to another has some benefit. These flexible circuits are made in a similar manner to rigid PCBs, where layers of circuitry and dielectric are laminated. The main difference is the material set used for construction. Typical flexible circuits start with a polymer film that is clad, laminated, or deposited with copper. A photolithography image with the desired circuit geometry is printed onto the copper, and the film is etched to remove the unwanted materials. The films are processed similar to that of rigid PCBs with a series of imaging, masking, drilling, via creation, plating, trimming, etc. The resulting circuit is flexible in such a way that as it is bent, the polymer film bends and supports the copper circuitry in a way that it does not crack or break. These circuits are solderable and can have devices attached to provide some desired function. The are used in many electronic systems such as notebook computers, medical devices, displays, handheld devices, automobiles, and aircraft. These flexible materials can be used in high frequency applications where the material set and design features can often provide better electrical performance than a comparable rigid circuit.

Both rigid and flexible circuits are connected to the system in a variety of ways. In most cases, a portion of the circuitry is exposed to create a connection point in terminal. Once exposed, the terminal can be connected to another circuit or component by soldering, conductive adhesive, thermosonic welding, pressure, or some sort of connector.

### BRIEF DESCRIPTION

Embodiments for a method of forming a circuit bearing structure are provided. The method includes depositing a layer of thermoplastic particles on a surface, pressing and heating the layer of thermoplastic particles to create a contiguous thermoplastic film, and forming one or more circuit structures in the contiguous thermoplastic film.

Embodiments for another method of forming a circuit bearing structure are provided. The method includes providing a thermoplastic substrate having one or more circuit structures formed therein and exposed at a first surface thereof. The method also includes depositing a layer of thermoplastic particles on the first surface, and pressing and heating the layer of thermoplastic particles to create a contiguous thermoplastic material including the thermoplastic substrate and the layer of thermoplastic particles.

Embodiments for another method of forming a circuit bearing structure are also provided. The method includes providing a thermoplastic substrate having one or more circuit structures formed therein and exposed at a first surface thereof. The method also includes depositing a layer of particles on the first surface, the layer of particles including particles of a thermoplastic material and particles of a photo-imageable material. The method also includes exposing the layer of particles to masked UV light to cure portions of the layer of particles and leave other areas of the particles uncured. Uncured particles are removed from the first surface forming one or more recesses in a layer of thermoplastic formed from the particles; and copper is deposited in the one or more recesses.

### DRAWINGS

Understanding that the drawings depict only exemplary embodiments and are not therefore to be considered limiting in scope, the exemplary embodiments will be described with additional specificity and detail through the use of the accompanying drawings, in which;

FIG. 1 is cross-sectional views of example stages in a process where a layer of LCP powder is used to form an LCP film;

FIGS. 2A and 2B are cross-sectional views of example stages in another process where a layer of LCP powder is used to form an LCP film having 3D features therein;

FIG. 3 is cross-sectional views of example stages in a process of forming circuit structures in the 3D features of the LCP film of FIG. 2B;

FIG. 4 is cross-sectional views of example stages in another process for forming circuit structures in the 3D features of the LCP film of FIG. 2B;

FIGS. 5A-5D are cross-sectional views of example stages in another process for creating circuit features in an LCP film;

FIG. 6 is a cross-sectional view of another example circuit structure having LCP powder applied around circuit structures;

FIG. 7 is a cross-sectional view of another example circuit structure having LCP powder that is UV curable applied around circuit structures;

FIG. 8 is a cross-sectional view of a structure in which the dielectric properties of an LCP film/layer vary in different lateral areas or within different layers/vertical areas;

FIG. 9 is a cross-sectional view of a structure in which an additive to the LCP powder, such as copper, nickel, or ceramic, acts as a thermal transfer or shielding material;

FIGS. 10A-10H are cross-sectional views of example stages of creating a structure using LCP powder; and

FIG. 11 is a cross-sectional view of an example structure in which LCP powder is used as over mold to provide mechanical and environment protection to a die.

### DETAILED DESCRIPTION

In general, flexible circuits fill a needed function within the electronics industry. They can be considered expensive compared to some rigid PCB products. They do have some limitations regarding layer count or feature registration and they are generally used for small or elongated applications. Rigid PCBs and package substrates experience challenges as the feature sizes and line spacing are reduced to achieve further miniaturization and increased circuit density. The use of laser ablation has become increasingly used to create the via structures for fine line or fine pitch structures. The use of lasers allows localized structure creation, where the processed circuits are plated together to create via connections from one layer to another. As density increases, the laser processed via structures can experience significant taper, carbon contamination, layer to layer shorting during the plating process due to registration issues, and high resistance interconnections that may be prone to result in reliability issues. The challenge of making fine line PCBs often relates to the difficulty in creating very small or blind and buried vias in multi-layer stack-ups. Many technologies can make fine line and space circuits on one layer, while constructing reliable stacks of many layers is a challenge and barrier to further node shrink and complexity.

The subject matter described herein is aimed primarily at liquid crystal polymer (LCP) as a dielectric material to produce high density, higher performance multi-layer electrical circuits capable of directly attaching silicon die and other components on a very fine termination pitch. LCP has been used in applications where the base LCP film material is laminated with sufficient heat and pressure to cause multiple layers of LCP to bond to each other or slightly melt so that the multiple layers combine to resemble a single contiguous piece of LCP. During this lamination, the temperature is controlled to be close to, but below the melt temperature of LCP, such that the LCP does not cross over into the liquid phase and lose its definition, or have significant material, or circuit movement or circuit embossing. A limitation of this use of LCP is reached when a circuit stack beyond four or five layers is desired with fine geometry contained within the stack. The sequential lamination required to build multi-layer constructions challenges the material set because previously created fusion bond interfaces weaken and embedded circuitry is disrupted in subsequent laminations. The physical bond of the LCP to LCP can be disrupted, and in general the bond of LCP to copper can be inadequate to survive required reliability in many cases, resulting in delamination. This method of manufacturing requires that the heated and softened LCP sheet material be close enough to liquid temperature to flow between the circuit traces and fill the gaps and bond properly when cooled while at the same time not be too soft such that the material moves or circuit features are disrupted. The nature of this process have been difficult to control and has limited the use of LCP.

Impedance control is another thing that can be important, particularly for high speed applications. It can also be important to surround the circuits with a low loss dielectric to retain as much of the input signal as possible. Most dielectrics used I printed circuit fabrication are supplied in sheet form and the bonding layers are primarily sheet form as well. As dielectrics get thinner to maintain impedance targets, most of those materials are of contiguous content across the sheet and the designer must live with the provided properties without much opportunity for modification. To further challenge the reduction in circuit size and increase routing density, the commercial LCP film materials available have a lower thickness limit of approximately 25 microns, which creates a barrier to tight impedance control as lines and spaces and circuit geometries shrink. In order to match the impedance targets for high performance digital wireless applications, when circuit size line and space shrinks, the dielectric spacing must often decrease to maintain the proper dielectric to metal geometry ratios. This can be difficult with conventional extruded film materials.

The subject matter described herein utilizes the excellent dielectric and mechanical properties of LCP while leveraging the polymer property of LCP being a thermoplastic. As a thermoplastic, LCP can be heater near its flow temperature or melted to alter shape and geometry many times while returning to solid state in a controlled manner with controlled dimensions. The advent of 3D printing of polymers has established the infrastructure and capability to use thermoplastics in powder form for a variety of processing techniques.

The subject matter described herein uses Liquid Crystal Polymer (LCP) thermoplastic as a powder dielectric for printed circuit fabrication as well as any non-circuit construction that would strive to replicate a product made by injection molding or 3D printing of other thermoplastics such as ABS or PEEK. The subject matter herein uses a combination of LCP powder, LCP films, dielectric material either in liquid or sheet form and a series of additive and subtractive steps to create thin high performance circuit structures that can replicate or replace conventional technologies as well as provide opportunities for increased circuit density. LCP material has many benefits from an electrical and mechanical standpoint. It has a lower dielectric constant than many traditional materials, can be processed to accept direct metal deposition, does not absorb moisture, and has low signal loss at high frequency.

In one embodiment, LCP powder is used to create a base or core layer of LCP for a circuit construction. As mentioned, existing LCP firm is produced with an extrusion process converting LCP formed pellets into a film that has a variety of thicknesses generally in the 15 micron range down to 25 microns. Extrusion of films thinner than 25 microns is difficult due to material handling while other polymers such as Ultem polyamide and Kapton polyimide and some polyesters are available thinner. Existing LCP film is also expensive and constructing a base layer from powder has advantages.

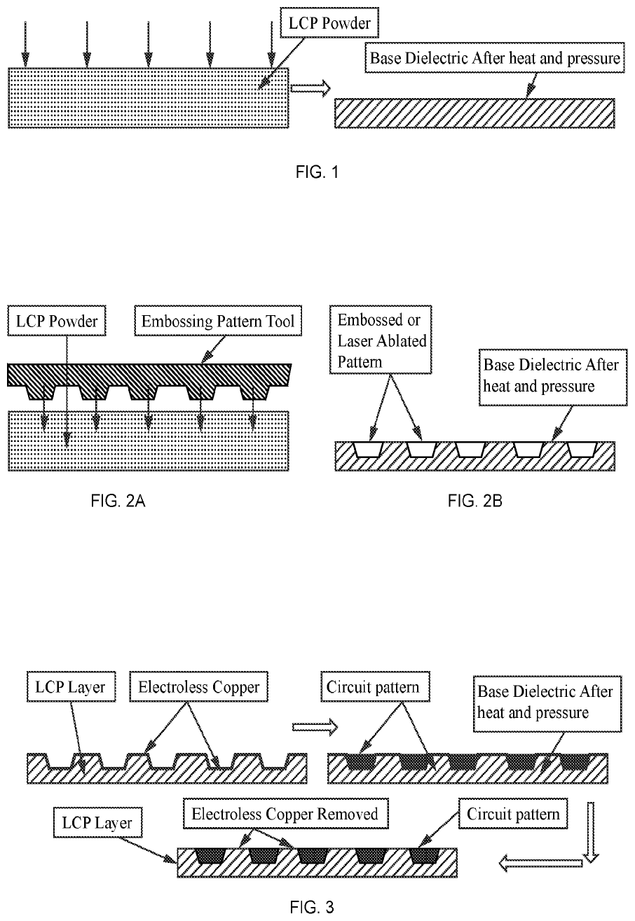

FIG. 1 is cross-sectional views of example stages in a process where a layer of LCP powder is cast or applied to a planar surface with gross control of the amount of powder applied to achieve a rough base thickness such that when heat and pressure is applied the LCP is fused together into a contiguous substrate of desired thickness. This is similar to a compression molding process. The application of LCP powder layer can be controlled by electrostatic charge, powder granular size, screen printing, and/or pre-heat pressing to achieve a desired powder layer density and height such that when heat and pressure is applied the powder stack or layer melts and bonds together to create a layer of desired thickness with few or no air pockets or bubbles.

The resultant LCP layer can be used for circuit fabrication in the same way as existing extruded LCP film is used. This powder fused LCP layer can have lateral dimensions that are the same as existing production panels of 9×12, 12×12, or 18×24 inches, 200 or 300 mm round wafer, or other existing or non-existing sizes. The powder fusion process naturally relieves stress within the substrate and the process allows for a custom fabrication of LCP film or substrate without the roll-to-roll type extrusion process. Particle sizes in the LCP powder of less than 200 microns down to 1 micron are desired. Post fusion substrate thicknesses can be any dimension desired, with the ability to achieve thickness of 25 micron or less including 12 and 10 micron thicknesses. A base of copper or other supporting material can be used to add mechanical and handling support in a sacrificial manner, or in the case of copper the base can serve as the base for a circuit layer. In most commercial circuit fabrication applications, extruded LCP film is processed to bond or deposit copper onto one or both sides of the LCP film. The subject matter described herein, in contrast, forms an LCP film via fusion of powdered LCP onto a copper foil. Such LCP powder can be fused by two plates that are pressed together with the LCP powder in between or via a roller which applies heat and pressure to the LCP powder with a plate underneath the powder. In the roller process, the LCP powder is placed on a carrier, such as a copper foil. The carrier and LCP powder and then fed through opposing hard surfaces that are separated from one another by the desired thickness of the resulting LCP layer. Using this process, an LCP layer of desired thickness, length, and width can be created.

FIGS. 2A and 2B are cross-sectional views of example stages in a process of creating another example in which one or more of the surfaces/plates pressing the LCP powder into a film are not flat, i.e., they define three dimensional features thereon. This topography can emboss a pattern into the LCP powder to define impressions, depressions, raised regions or planar regions as desired. Laser ablation can also be used in addition to or instead of features on the plate(s) to create desired three dimensional features in the LCP film.

FIG. 3 is cross-sectional views of example stages in a process of forming circuit structures in such an LCP film having three-dimensional features. In this example, the three-dimensional features include recesses which can serve as a target for circuit formation by plating electroless copper onto the surfaces and electroplating copper using the surface copper as a plating bus. In the example shown in FIG. 3, the LCP film is formed with recesses therein and copper is electrolessly plated over the entire area in which the recesses are present, such that the copper is plated in the recesses as well as areas between the recesses. The electroless copper can have a thickness in the 1 to 3 micron range or less. Copper can then be deposited in the recesses to form circuit structures via electroplating where the electroless copper serves as the electrolytic plating bus. Exposed electroless copper between the recesses can then be removed via etching to de-couple adjacent recesses now filled with copper.

A seed or catalyst (e.g., containing palladium) can be used to treat the surface of the LCP prior to electroless plating to assist the initiation of plating. In some examples, the features on surfaces of the compression members that compress the powdered LCP have smooth surfaces or a skin effect to assist with releasing from the LCP after compression. Smooth surfaces on the compression members creates smooth surfaces on the resultant LCP film. These smooth surfaces on the LCP film may not accept electroless copper plating as well, so a mild plasma or permanganate treatment can be applied to create microscopic roughness/porosity that assists with copper adhesion with or without a palladium based catalyst application. Features in the LCP film created with laser ablation typically have a roughness such that plasma or permanganate treatment is not needed.

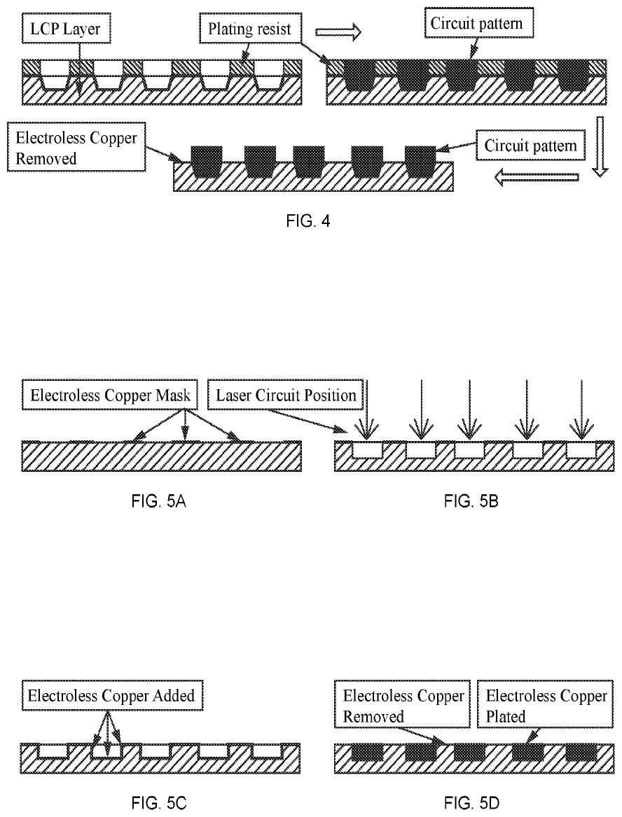

FIG. 4 is cross-sectional views of example stages in another process for creating circuit structures in recesses of an LCP film. This example is similar to the process with respect to FIGS. 3A-3C, except that plating resist is added to the substrate after electroless plating. The plating resist can be deposited such that the recesses are exposed and areas between the recesses are covered by the plating resist. Then, electrolytic copper plating can be used to fill the recesses up to or above the surface of the LCP film. This process is beneficial because it controls the location and geometry of the electrolytic plated circuits without adding electrolytic plated copper to the areas between the recesses, which are covered by plating resist. This, in turn, benefits the subsequent etching process by keeping the copper that needs to be etched away thin-having no addition copper added during electrolytic plating. It also allows for the electrolytic copper to be plated higher than the surface of the recesses defined in the LCP film.

FIGS. 5A-5D are cross-sectional views of example stages in another process for creating circuit features in an LCP film. This process starts with an LCP film formed via fused LCP powder as disclosed herein. The LCP film is flat across an entire area (e.g., the entire film), that is, no three-dimensional features are present. The surface of the LCP film is then plating the electroless copper, either directly or with the use of a catalyst. The thin copper layer is then imaged to provide the pattern geometry and etched to expose the surface the LCP film where the resultant circuit will be present. A UV or laser system can then be used to ablate the exposed surface of the LCP film to create recesses. The remining pattern of thin copper layer acts as a mask for the ablation. The benefit of using the metal mask is that with proper laser settings, the LCP material can be ablated with a lower power setting such that the metal is not ablated or damaged and the masking effect enables relatively straight sidewalls and controlled depth with precision geometry for the recesses. The resulting recesses can be plated with electroless copper and then electroplated to create the circuit pattern in the recess. Electroless copper between the recesses can be removed via etching.

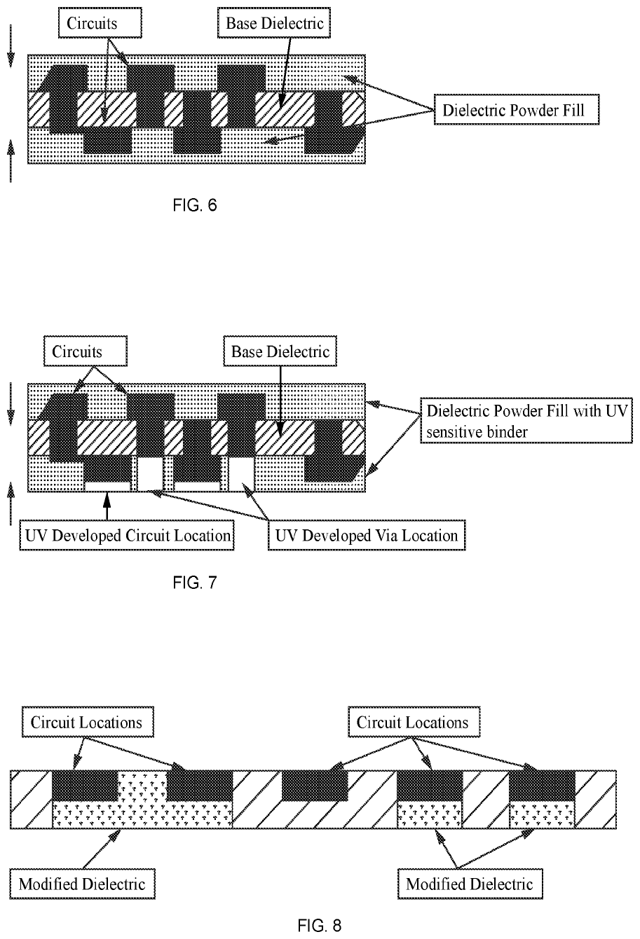

FIG. 6 is a cross-sectional view of another example circuit structure. As lines and spaces reduce, the thickness of the dielectric can be important for dielectric separation to be maintained with electrical properties of the dielectric material tuned for the desired impedance and loss environment. As the dielectric layer thickness is reduced, it is increasingly difficult to process the corresponding films. LCP in powder form can be applied to a substrate having exposed circuit patterns in an LCP substrate and the powder can be fusion bonded to cover or surround the circuit patterns. A lamination process or thermal cycle that melts the particles quickly without melting the base LCP substrate can be used. LCP particles having a small size and correspondingly lower thermal mass can be used to aid in melting the particles without melting the base LCP substrate. Such a process can be performed on one or both sides of a LCP base.

LCP powder can be used as described with respect to FIG. 6 due to the fact that LCP is a thermoplastic that will bond to itself after processing, but other materials could also be used instead of LPC such as ABF, PEEK, polyimide, polyamide, Teflon, ceramics, or fine glass. In yet another example, the powder is a mixture of any of the aforementioned materials including, for example, LCP plus Teflon, LCP plus ABF, LCP plus Born Nitride or Alumina, and LCP plus a bonding agent that has a lower melt point.

In some examples, an electrostatic charge may be used to control the location of dry powder particles until they are fusion bonded together. In some examples, it may be desirable to place the particles in suspension to create a slurry, paste, deionized water, or ink such that the materials can be deposited in a controlled manner without loose particles residing where not desired. Such a semi-liquid dielectric can be processed to drive off the suspension material and leave the proper dielectric materials in the desired locations with precise thickness and dimension.

FIG. 7 is a cross-sectional view of another structure formed as described with respect to FIG. 6, with a mixture of dry particles that can be fusion bonded together. In this example, a photo-imageable material is included in the mixture or suspension. After the dry particles are deposited over and/or around the circuit structures, a photolithography process can be performed where areas of the dry particles that are exposed to the UV light cure and remain in place whereas areas not exposed to UV light do not cure and can be developed away. Recesses that can later be plated/filled with copper can be formed in this manner to form additional circuit structures such as vias. This process of depositing and curing powder via UV exposure can be repeated multiple times to create a multi-layer circuit stack.

FIG. 8 is a cross-sectional view of another structure in which the dielectric properties of an LCP film/layer vary in different lateral areas or within different layers/vertical areas. LCP is accepting of dopants or additives that have a composite effect mechanically and electrically, so different areas of the LCP within a resultant circuit structure can have different dielectric properties. In an example, the different dielectric properties in proximity or in contact with the signal line provides an altered field that controls performance or provides a desirable alteration in performance different from that of a common dielectric.

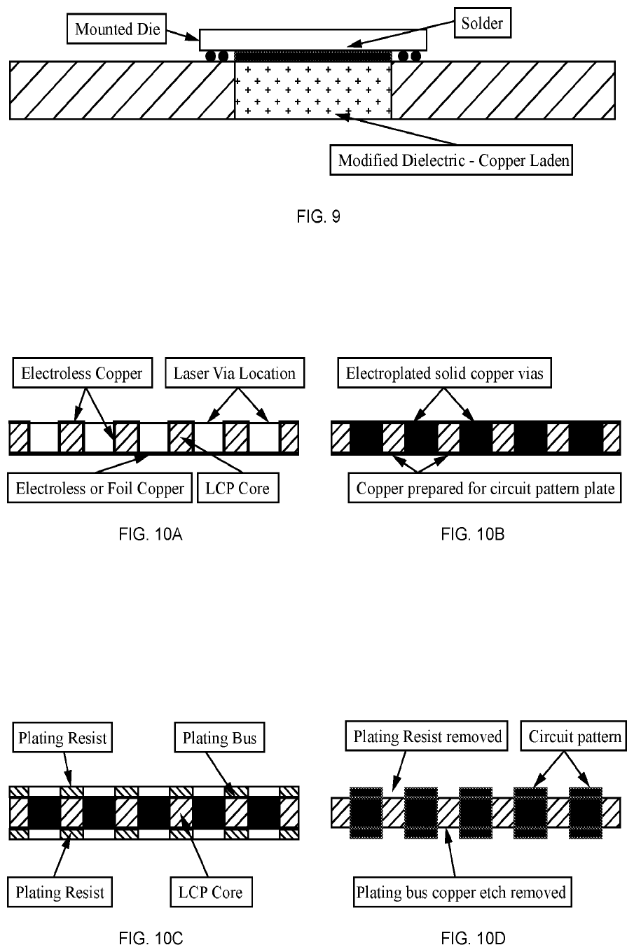

FIG. 9 is a cross-sectional view of another structure in which an additive to the LCP powder, such as copper, nickel, or ceramic, acts as a thermal transfer or shielding material. This can be added to select areas as discussed above with respect to FIG. 8 to create a thermal management or shielding region within the polymer matrix. As shown in FIG. 8, such a region can also be used to solder mount a die onto a surface having such copper or nickel additives therein. That is, a die can be solder mounted to a region having LCP with copper or nickel additives therein. The region with copper or nickel additives can also provide thermal transfer from the die to the backside of the substrate or shielding for the die from the backside of the substrate. Thermal transfer and/or connections to the ground plane can also be formed through the LCP on one or more sides of the region having additives therein.

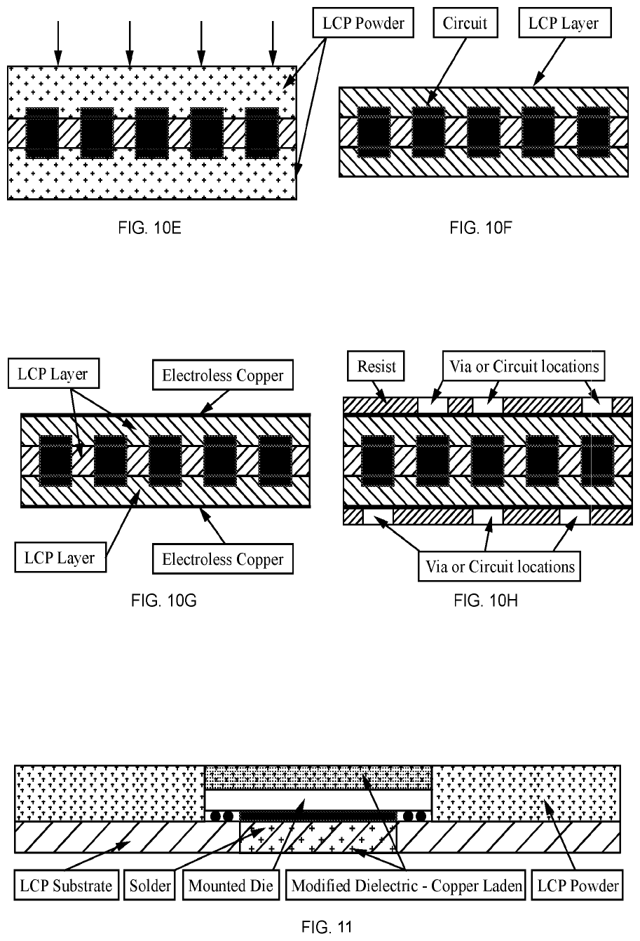

FIGS. 10A-10H are cross-sectional views of example stages of creating another structure. The construction can start with a core that can be extruded LCP film or fusion bonded LCP film. The core can be laser drilled, plated with electroless copper, or in the event the core layer is commercial LCP film, the factory applied copper foil can be etched down to approximately 2 to 3 microns to approximate an electroless copper plating as shown in FIG. 10A. Solid copper vias are electroplated through the core layer as shown in FIG. 10B. Plating resist is applied to the thin layer of copper and imaged with the desired circuit pattern as shown in FIG. 10C. Electrolytic copper plating is applied to the circuit regions defined by the imaged plating resist and the circuit traces are grown by the electrolytic copper plating process as shown in FIG. 10D. This process is conducted on one side only, one side at a time then the other side, or both sides at one time. The plating resist is stripped, and the copper used for the electrolytic plating operation is etched away as shown in FIG. 10E. The core layer is further processed by adding an LCP powder layer, which under heat and pressure merges with the core layer creating a platform for further multi-layer construction as shown in FIG. 10F. Electroless copper can be added to the exposed surfaces of the new LCP layers with plating resist added to define the next layer of circuit patterns, including via locations as shown in FIG. 10G. As described above, the addition of powder layers fills between the exposed circuit patterns without adhesive or bond materials and the process sequence can be repeated as many times as needed to create the full circuit stack desired with the final layer as solder mask as shown in FIG. 10H.

FIG. 11 is a cross-sectional view of an example structure in which LCP powder is used as over mold to provide mechanical and environment protection to a die. LCP powder that is fusion bonded can be used as over mold for any of the structures and embodiments disclosed herein. The example of FIG. 11 illustrates the LCP powder to over mold a semiconductor die mounted to an LCP substrate having a copper laden underfill as shown in FIG. 8. In an example, an area in the LCP over mold above the semiconductor die can have copper additive therein for thermal management and/or shielding.

Although LCP powder has been described as the primary powder used herein, other thermoplastics such as ABS, Polyolefin, and Ultem can be used. The principles described herein apply to any LCP substrate that may benefit from the addition of 3D printed LCP powder to replicate or simulate an injection molded operation without the need for insertion of the substate into a mold with likely lower temperature and pressure needed to fuse the LCP powder particles without disrupting the base LCP material within the substrate or surrounding features. Use of LCP powder as a pure 3D printed polymer to simulate an injection molded LCP part is also included. Use of LCP powder as a 3D printed material follows conventional usage models where the powder is located in a precise manner with electrostatic control of location and thickness, then fused by heat and pressure and additively processed with multiple passes to create the final products. Another method is to apply a mass of LCP powder over a surface with a desired thickness and depth of powder and selectively fuse the powder particles by heat and pressure only in select areas to achieve fusion where desired with non-fused regions remaining powder and reused. Laster sintering or fusion is also an option with typically lower tolerance and resolution of features.

The benefits of the subject matter described herein are significant, as it allows for creating a customized and tunable dielectric matrix that can be deposited directly onto exposed circuits in a precise manner with controlled dimension and thickness to achieve density and signal integrity not possible with conventional commercially available film dielectric materials. The subject matter herein allows for mixing dielectric materials into a matrix providing customized dielectric properties on any layer or at any point within a given layer. The subject matter herein allows for application of dielectrics in thinner or thicker sections to refine dielectric separation in dimensions not available from commercial supply base. The subject matter herein allows for the use of photo-imageable binders to create circuit structures such as copper filled trenches and photo-imaged via locations rather than laser ablation with often requires a metal stop layer to prevent the laser beam from penetrating lower layer dielectric. The subject matter herein allows for application of high melt temperature polymers such as LCP or Teflon with a lower temperature binder such that the dielectric deposition can be processed below the melt temperature of the higher temperature materials. The subject matter herein allows for the mixture of various dielectric materials to create a customized tunable matrix containing any number of polymer, ceramic, or various additives to alter the dielectric or mechanical properties of the resultant circuit layer or multi-layer circuit stack. The subject matter herein allows for the dielectric matrix to be used as the primary dielectric for a given layer such that the material bonds layers to layers as well as contains the proper dielectric properties itself without a supporting base dielectric layer. The subject matter herein allows for the dielectric matrix to be used at a final layer as a solder mask rather than applying conventional solder mask with a high loss material and difficult to register at high resolution. The subject matter described herein allows for use of LCP powder as a strong alternative to currently available 3D printed polymers and thermoplastics used in printed powder or extruded filament applications.

1. A method of forming a circuit bearing structure, the method comprising:
depositing a layer of thermoplastic particles on a surface;
pressing and heating the layer of thermoplastic particles to create a contiguous thermoplastic film; and
forming one or more circuit structures in the contiguous thermoplastic film.

2. The method of claim 1, wherein the thermoplastic is liquid crystal polymer (LCP).

3. The method of claim 1, wherein pressing is performed by moving two opposing portions of a mold toward one another and squeezing the layer of thermoplastic particles therebetween.

4. The method of claim 1, wherein pressing is performed by moving the layer of thermoplastic particles and the surface the particles are on underneath a roller that squeezes onto the surface.

5. The method of claim 3, wherein at least one of the two opposing surfaces defines three-dimension features thereon that contact the layer of thermoplastic particles forming one or more recesses in a first surface of the contiguous thermoplastic film.

6. The method of claim 5, wherein forming one or more circuit structures includes:
plating the first surface of the thermoplastic film having the one or more recesses thereon with electroless copper;
plating the one or more recesses with electrolytic copper; and
etching the first surface of the thermoplastic film to remove copper between the recesses.

7. The method of claim 6, wherein forming one or more circuit structures includes:
depositing plating resist on the first surface after plating with electroless copper to cover areas between the recesses and expose the recesses; and
removing the plating resist after plating the one or more recesses with electrolytic copper.

8. The method of claim 1, wherein forming one or more circuit structures includes:
plating a first surface of the thermoplastic film with copper;
imaging the copper to expose the thermoplastic film in areas in which circuit structures are to be formed;
ablating the first surface of the thermoplastic film with a UV or laser to create recesses in the exposed areas of thermoplastic film;
plating the first surface of the thermoplastic film having the one or more recesses thereon with electroless copper;
plating the one or more recesses with electrolytic copper; and
etching the first surface of the thermoplastic film to remove copper between the recesses.

9. The method of claim 1, wherein depositing a layer of thermoplastic particles on a surface includes depositing a first additive particle in a first area along with the thermoplastic particles and excluding the first additive particle from a second area, whereby pressing and heating the layer of thermoplastic particles to create a contiguous thermoplastic film creates a thermoplastic film having a first region in which a material corresponding to the first additive particle is present and a second region in which the material corresponding to the first additive particle is not present.

10. The method of claim 9, wherein the first additive particle is composed of one of the following materials: polyimide, polyamide, ceramic, and glass.

11. The method of claim 9, wherein the first additive particle is composed of one of copper or nickel;
wherein the method further comprises soldering a die to the first surface at the first region.

12. The method of claim 11, comprising:
depositing a second layer of thermoplastic particles over the die; and
pressing and heating the second layer of thermoplastic particles to form a solid thermoplastic structure over the die.

13. The method of claim 12, wherein depositing a second layer of thermoplastic particles over the die includes depositing a second additive particle in a third area above the die and excluding the second additive particle from a fourth area, whereby pressing and heating the second layer of thermoplastic particles creates a solid thermoplastic structure having a third region above the die in which a material corresponding to the second additive particle is present, wherein the second additive particle is one of copper and nickel.

14. The method of claim 12, wherein the second layer of thermoplastic particles is composed of liquid crystal polymer (LCP).

15. A method of forming a circuit bearing structure, the method comprising providing a thermoplastic substrate having one or more circuit structures formed therein and exposed at a first surface thereof;
depositing a layer of thermoplastic particles on the first surface; and
pressing and heating the layer of thermoplastic particles to create a contiguous thermoplastic material including the thermoplastic substrate and the layer of thermoplastic particles.

16. The method of claim 15, wherein the thermoplastic substrate and the thermoplastic particles are composed of liquid crystal polymer (LCP).

17. A method of forming a circuit bearing structure, the method comprising
providing a thermoplastic substrate having one or more circuit structures formed therein and exposed at a first surface thereof;
depositing a layer of particles on the first surface, the layer of particles including particles of a thermoplastic material and particles of a photo-imageable material;
exposing the layer of particles to masked UV light to cure portions of the layer of particles and leave other areas of the particles uncured;
removing uncured particles from the first surface forming one or more recesses therein;
depositing copper in the one or more recesses.

18. The method of claim 17, wherein the thermoplastic particles are composed of liquid crystal polymer (LCP).
